(19) United States
(12) Patent Application Publication
(10) Pub. No.: US 2025/0318116 A1
(43) Pub. Date: Oct. 9, 2025

(54) MEMORY DEVICE AND METHOD OF FABRICATING SEMICONDUCTOR DEVICE

(71) Applicant: Winbond Electronics Corp., Taichung City (TW)

(72) Inventors: Yu-Ting Huang, Taichung City (TW); Kao-Tsair Tsai, Taichung City (TW)

(73) Assignee: Winbond Electronics Corp., Taichung City (TW)

(21) Appl. No.: 18/967,653

(22) Filed: Dec. 4, 2024

(30) Foreign Application Priority Data
Apr. 3, 2024 (TW) 113112798

(51) Int. Cl. H10B 41/30; H01L 21/3105; H10B 41/40

(52) U.S. Cl. CPC H10B 41/30; H01L 21/31051; H10B 41/40

(57) ABSTRACT

A memory device, including first stacked structures, second stacked structures, a dielectric structure, and a liner layer located on a substrate. A first opening is located between the first stacked structures. A second opening is located between the second stacked structures. The dielectric structure covers the first stacked structures and the second stacked structures and is filled in the second opening. The dielectric structure includes a first portion covering the first stacked structures and a second portion covering the second stacked structures. The liner layer is discontinuously embedded in the dielectric structure. The liner layer includes a first segment and a second segment. The first segment is embedded in the first portion of the dielectric structure. The second segment is embedded in the dielectric structure in the second opening. The first segment and the second segment are separated by the second portion of the dielectric structure.

### CROSS-REFERENCE TO RELATED APPLICATION

This application claims the priority benefit of Taiwan application serial no. 113112798, filed on Apr. 3, 2024. The entirety of the above-mentioned patent application is hereby incorporated by reference herein and made a part of this specification.

### BACKGROUND

### Technical Field

The disclosure relates to an integrated circuit and a method of fabricating the same, and in particular to a memory device and a method of fabricating a semiconductor device.

### Description of Related Art

As technology advances, various electronic products evolve towards the trend of becoming lighter, thinner, shorter, and smaller. Hence, the critical dimension of memory devices also gradually decreases, thereby bringing more and more challenges to photolithography processes. Due to the resolution of known photolithography processes approaching theoretical limits, manufacturers have begun to shift towards the self-aligning double patterning (SADP) method to overcome optical limits and improve the integration density of memory devices. However, as pattern densities are currently different at the center and edges of the array area, the etching process faces the loading effect, resulting in inconsistent contours of the dielectric layers at the center and edges of the memory array area. This further leads to excessive stress imposed by the chemical mechanical polishing process on the device, and even causes cracks in active areas, affecting the yield of the process.

### SUMMARY

The embodiment of the disclosure provides a memory device and a method of fabricating the same to reduce stress imposed by a chemical mechanical polishing process and avoid causing a crack in an active area, thereby improving a yield of the process.

A memory device in the embodiment of the disclosure includes a substrate, multiple first stacked structures, multiple second stacked structures, a dielectric structure, and a liner layer. The first stacked structures are located on the substrate, and a first opening is located between the first stacked structures. The second stacked structures are located on the substrate, and a second opening is located between the second stacked structures. The dielectric structure covers the first stacked structures and the second stacked structures and is filled in the second opening. The dielectric structure includes a first portion and a second portion. The first portion covers the first stacked structures and the second portion covers the second stacked structures. The liner layer is discontinuously embedded in the dielectric structure. The liner layer includes a first segment and a second segment. The first segment is embedded in the first portion of the dielectric structure. The second segment is embedded in the dielectric structure in the second opening. The first segment and the second segment are separated by the second portion of the dielectric structure.

A method of fabricating a semiconductor device in the embodiment of the disclosure at least includes the following steps. A first stacked structure and a second stacked structure are formed on a substrate. A first dielectric layer and a liner layer are formed on the first stacked structure and the second stacked structure. A step height is formed in the dielectric layer and the liner layer on the second stacked structure. At least a portion of the step height is removed to form a groove. A dielectric material is formed on the liner layer and in the groove. A planarization process is performed on the dielectric material to form a second dielectric layer. A stop layer is formed on the second dielectric layer.

In the embodiment of the disclosure, the step height on the second stacked structure is removed to reduce the stress imposed by the chemical mechanical polishing process on the second stacked structure, and avoid causing a crack in the active area below the second stacked structure. As a result, the yield of the process is improved.

### BRIEF DESCRIPTION OF THE DRAWINGS

FIGS. 1A to 1G are cross-sectional schematic diagrams of a fabrication process of a memory device in a memory array area according to the disclosure.

FIG. 2 is a cross-sectional schematic diagram of a memory device in a peripheral area according to the disclosure.

### DESCRIPTION OF THE EMBODIMENTS

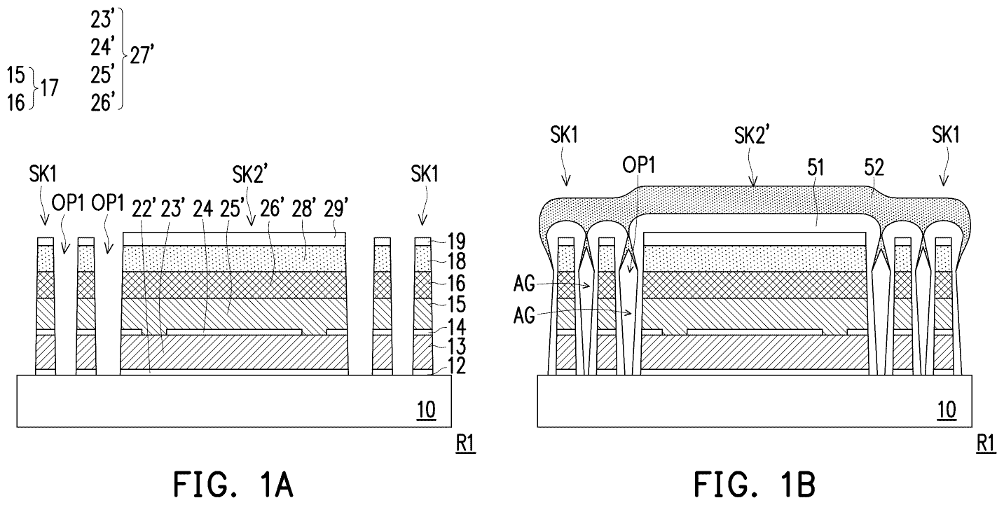

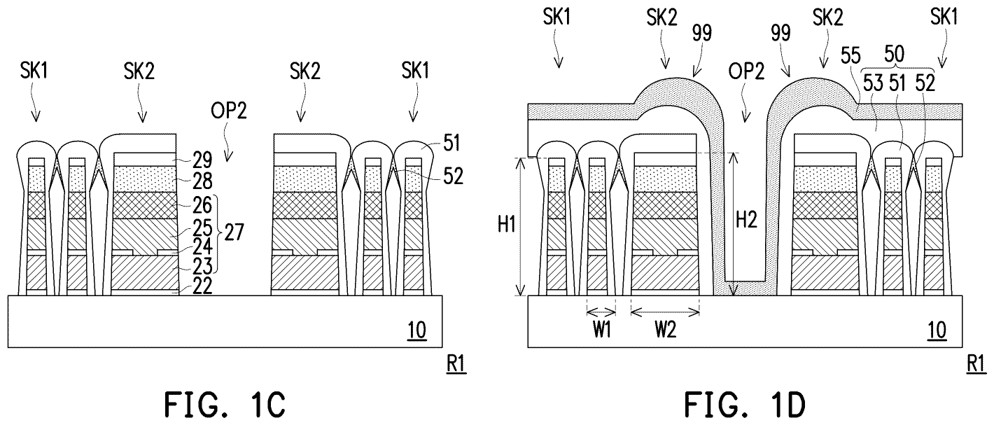

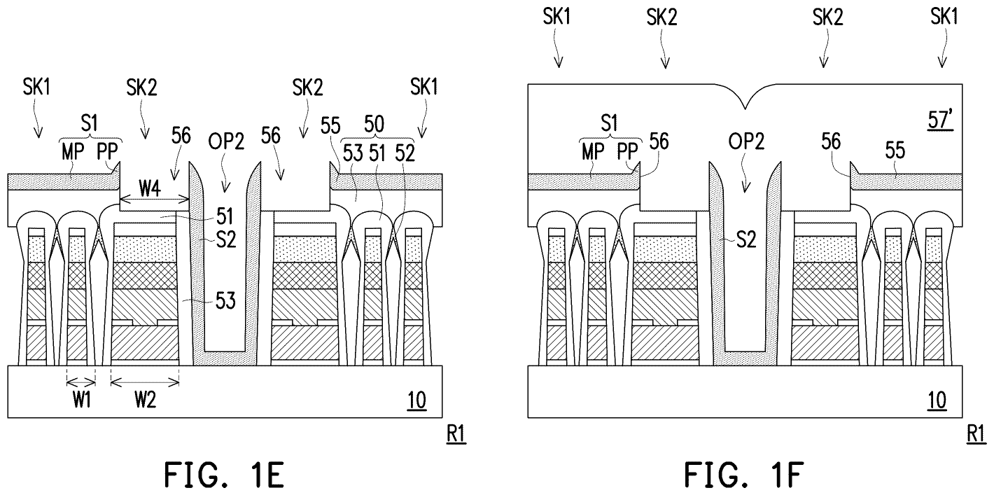

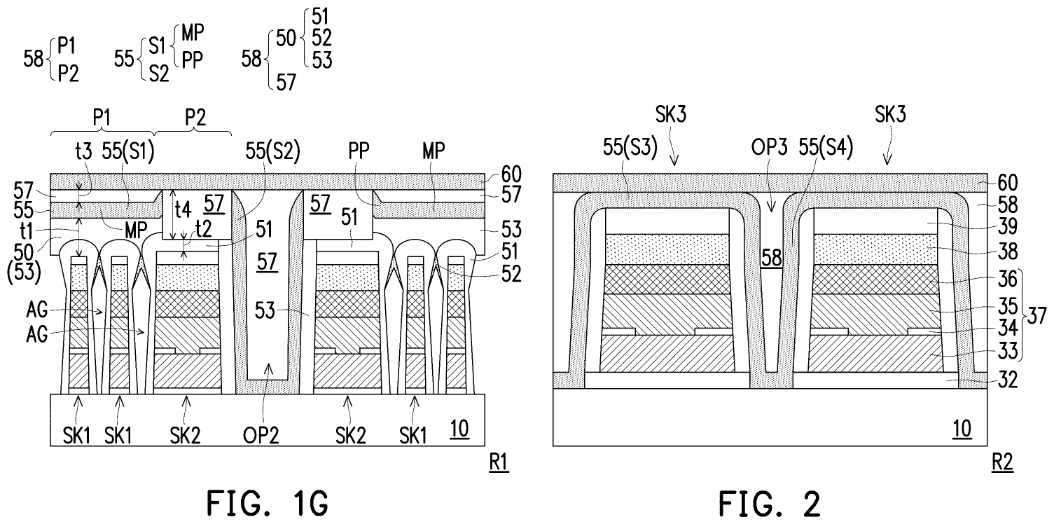

Referring to FIG. 1A, multiple first stacked structures SK1 and multiple second stacked structures SK2′ are formed in a memory array area R1 of a substrate 10. The first stacked structure SK1 includes multiple word lines. The first stacked structure SK1 includes a tunneling dielectric layer 12, a floating gate 13, an inter-gate dielectric layer 14, a control gate 17, a top cap layer 18, and a hard mask layer 19. A first opening OP1 is located between the adjacent first stacked structures SK1 and between the first stacked structure SK1 and the second stacked structure SK2′ adjacent to each other. The control gate 17 may serve as a word line. The second stacked structure SK2′ includes a gate dielectric layer 22′, a gate conductor layer 27′, a top cap layer 28′, and a hard mask layer 29′. The gate conductor layer 27′ may include a semiconductor layer 23′, a semiconductor layer 25′, and a conductor layer 26′ electrically connected to one another. The gate conductor layer 27′ may further include a dielectric layer 24′.

The tunneling dielectric layer 12, the gate dielectric layer 22′, the inter-gate dielectric layer 14, and the dielectric layer 24′ are, for example, silicon dioxide. The material of the floating gate 13 includes semiconductor (e.g., polysilicon). The control gate 17 may include a semiconductor layer 15 and a conductor layer 16. The semiconductor layer 15 is, for example, polysilicon. The conductor layer 16 is, for example, tungsten. The top cap layer 18 and the top cap layer 28′ are, for example, silicon nitride. The hard mask layer 19 and the hard mask layer 29′ are, for example, silicon dioxide.

Referring to FIG. 1B, a dielectric layer 51 and a dielectric layer 52 are formed on and around the first stacked structure SK1 and the second stacked structure SK2′. The dielectric layer 51 and the dielectric layer 52 include silicon dioxide respectively. The dielectric layer 51 and the dielectric layer 52 do not fill the first opening OP1. Thus, air gaps AG are formed in the dielectric layer 51 and the dielectric layer 52.

Referring to FIG. 1C, the dielectric layer 52 on the dielectric layer 51 is removed. Subsequently, photolithography and etching processes are performed to form a second opening OP2 in the dielectric layer 51 and the second stacked structure SK2′. The second opening OP2 is larger than the first opening OP1. The second stacked structure SK2′ is patterned into multiple second stacked structures SK2. The second stacked structure SK2 includes a gate dielectric layer 22, a gate conductor layer 27, a top cap layer 28, and a hard mask layer 29. The gate conductor layer 27 may include a semiconductor layer 23, a semiconductor layer 25, and a conductor layer 26 electrically connected to one another. The gate conductor layer 27 may further include a dielectric layer 24. The gate conductor layer 27 may serve as a select gate. Therefore, the first stacked structure SK1 is also referred to as a word line structure, and the second stacked structure is referred to as a select gate structure.

Referring to FIG. 1D, a dielectric layer 53 and a liner layer 55 are formed on the first stacked structure SK1 and the second stacked structure SK2 and in the second opening OP2. The dielectric layer 53 is, for example, silicon dioxide. The dielectric layer 53 along with the dielectric layer 51 and the dielectric layer 52 are collectively referred to as a first dielectric layer 50. The material of the liner layer 55 is different from the material of the first dielectric layer 50. The liner layer 55 may be a nitride, such as silicon nitride, silicon oxynitride, or a combination thereof.

In this embodiment, a height H2 of the second stacked structure SK2 is greater than a height H1 of the first stacked structure SK1, and a width W2 of the second stacked structure SK2 is greater than a width W1 of the first stacked structure SK1. Therefore, the first dielectric layer 50 and the liner layer 55 on the second stacked structure SK2 protrude from the first dielectric layer 50 and the liner layer 55 on the first stacked structure SK1 due to the load effect of etching, thereby forming a step height 99 near the second opening OP2 on the second stacked structure SK2.

Referring to FIG. 1E, after the first dielectric layer 50 and the liner layer 55 are formed, photolithography and etching processes are performed to partially or completely remove the step height 99 on the second stacked structure SK2 (including a portion of the liner layer 55 and a portion of the first dielectric layer 50) so as to form multiple grooves 56. The depth of the grooves 56 may be controlled according to the actual requirements. For example, the dielectric layer 51, the dielectric layer 52, or the dielectric layer 53 of the first dielectric layer 50 may be exposed at a bottom of the groove 56. A width W4 of the groove 56 may be greater than, equal to, or less than the width W2 of the second stacked structure SK2. The groove 56 divides the liner layer 55 into a first segment S1 and a second segment S2. The first segment S1 covers the first stacked structure SK1. The first segment S1 includes a main portion MP and a protruding portion PP. The second segment S2 remains in the second opening OP2, around a side wall of the second stacked structure SK2.

Referring to FIG. 1F, a dielectric material 57′ is formed on the liner layer 55, which is located on the first stacked structure SK1 and the second stacked structure SK2, and in the groove 56. The dielectric material 57′ also fills the second opening OP2.

Referring to FIG. 1G, with the protruding portion PP of the first segment S1 and the second segment S2 of the liner layer 55 being polishing stop layers, a planarization process (e.g., a chemical mechanical polishing process) is performed to partially remove the dielectric material 57′, thereby forming a second dielectric layer 57. The second dielectric layer 57 and the first dielectric layer 50 compose a dielectric structure 58. Next, a stop layer 60 is formed on the dielectric structure 58. The stop layer 60 is, for example, silicon nitride. Since the step height 99 has been removed, the stress on the second stacked structure SK2 caused by the step height 99 during the chemical mechanical polishing process can be prevented, further avoiding causing a crack in an active area, located near the air gaps AG, of the substrate 10 below the second stacked structure SK2.

Referring to FIG. 2, in some embodiments, multiple third stacked structures SK3 are also formed in a peripheral area R2 of the substrate 10 during the aforementioned processes. The third stacked structure SK3 includes a gate dielectric layer 32, a gate conductor layer 37, a top cap layer 38, and a hard mask layer 39. The gate conductor layer 37 may include a semiconductor layer 33, a semiconductor layer 35, and a conductor layer 36 electrically connected to one another. The gate conductor layer 37 may further include a dielectric layer 34.

Referring to FIG. 2, the dielectric structure 58 is also located in a third opening OP3 between the third stacked structures SK3. The liner layer 55 is also formed in the dielectric structure 58 in the peripheral area R2. The stop layer 60 is also formed on the dielectric structure 58. The first opening OP1, the second opening OP2, and the third opening OP3 may also be referred to as a first gap OP1, a second gap OP2, and a third gap OP3.

Referring to FIG. 1G, the dielectric structure 58 in the embodiment of the disclosure further includes multiple first portions P1 and multiple second portions P2. The first portions P1 cover the first stacked structures SK1, and the second portions P2 cover the second stacked structures SK2. The first dielectric layer 50 and the second dielectric layer 57 in the first portion P1 of the dielectric structure 58 are separated by the liner layer 55. The second portions P2 are devoid of the liner layer 55, and the first dielectric layer 50 (e.g., the dielectric layer 51 and the dielectric layer 53) is in contact with the second dielectric layer 57. The second dielectric layers 57 in the second portions P2 are in contact with the stop layer 60 as well as the protruding portion PP of the first segment S1 of the liner layer 55 and a side wall of the second segment S2 of the liner layer 55.

A thickness t1 of the first dielectric layer 50 (e.g., the dielectric layer 51 and the dielectric layer 53) in the first portion P1 of the dielectric structure 58 is greater than a thickness t2 of the first dielectric layer 50 (e.g., the dielectric layer 51) in the second portion P2 of the dielectric structure 58. A thickness t4 of the second dielectric layer 57 in the second portion P2 of the dielectric structure 58 is greater than a thickness t3 of the second dielectric layer 57 in the first portion P1 of the dielectric structure 58.

Referring to FIGS. 1G and 2, the liner layer 55 is discontinuously embedded in the dielectric structure 58. The liner layer 55 may include multiple first segments S1, second segments S2, third segments S3, and fourth segments S4. The first segments S1 and the second segments S2 are located in the memory array area R1 while the third segments S3 and the fourth segments S4 are located in the peripheral area R2. In the memory array area R1, the first segments S1 of the liner layer 55 are embedded in the first portions P1 of the dielectric structure 58. The first segment S1 of the liner layer 55 is sandwiched between the first dielectric layer 50 and the second dielectric layer 57 so as to separate the first dielectric layer 50 and the second dielectric layer 57. In the memory array area R1, the second segment S2 is embedded between a dielectric layer 57 and the dielectric layer 53 in the second opening OP2. The first segments S1 and the second segments S2 are separated by the second portions P2 of the dielectric structure 58.

Referring to FIG. 1G, each of the first segments S1 of the liner layer 55 includes the main portion MP and the protruding portion PP. The protruding portion PP is located at an end of the main portion MP and is connected to the main portion MP. The protruding portion PP protrudes from a top surface of the main portion MP and extends towards the stop layer 60. Top ends of the protruding parts PP of the first segments S1 of the liner layer 55 are in contact with the stop layer 60. The protruding parts PP separate the second dielectric layers 57 in the first portions P1 of the dielectric structure 58 from the second dielectric layers 57 in the second portions P2. A lower portion of the second segment S2 of the liner layer 55 is embedded between the dielectric layer 57 and the dielectric layer 53 in the second opening OP2 while an upper portion of the second segment S2 is located between the dielectric layer 57 and the second dielectric layer 57, wherein the second dielectric layer 57 is in the second portion P2. Top ends of the upper parts of the second segments S2 of the liner layer 55 are higher than the top surfaces of the main parts MP of the first segments S1. The top end of the upper portion of the second segment S2 of the liner layer 55 is in contact with the stop layer 60.

Referring to FIG. 2, in the peripheral area R2, the third segment S3 of the liner layer 55 covers the third stacked structures SK3. In the peripheral area R2, the fourth segment S4 is embedded in the dielectric structure 58 in the third opening OP3. The third segment S3 and the fourth segment S4 of the liner layer 55 are connected, and the third segment S3 is in contact with the stop layer 60. In other words, the liner layer 55 extends continuously in the peripheral area R2, covering the third stacked structure SK3 and over the third opening OP3. A top surface of the third segment S3 of the liner layer 55 and a top surface of the second dielectric layer 57 in the memory array area R1 may be coplanar.

In the embodiment of the disclosure, the step height on the second stacked structure is removed to reduce the stress imposed by the chemical mechanical polishing process on the second stacked structure, and avoid causing a crack in the active area below the second stacked structure. As a result, the yield of the process is improved.

What is claimed is:

1. A memory device, comprising:
a substrate, comprising a memory array area and a peripheral area;
a plurality of first stacked structures, located in the memory array area, wherein a first opening is located between the plurality of first stacked structures;
a plurality of second stacked structures, located in the memory array area, wherein a second opening is located between the plurality of second stacked structures;
a dielectric structure, covering the plurality of first stacked structures and the plurality of second stacked structures and filled in the second opening, wherein the dielectric structure comprises a plurality of first portions and a plurality of second portions, the plurality of first portions covering the plurality of first stacked structures, and the plurality of second portions covering the plurality of second stacked structures; and
a liner layer, discontinuously embedded in the dielectric structure, wherein the liner layer comprises:
a first segment, embedded in the plurality of first portions of the dielectric structure; and
a second segment, embedded in the dielectric structure in the second opening,
wherein the first segment and the second segment are separated by the plurality of second portions of the dielectric structure.

2. The memory device according to claim 1, wherein the dielectric structure comprises a first dielectric layer and a second dielectric layer, and the first segment of the liner layer is sandwiched between the first dielectric layer and the second dielectric layer in the first portion of the dielectric structure.

3. The memory device according to claim 2, wherein the first dielectric layer is in contact with the second dielectric layer in the plurality of second portions of the dielectric structure.

4. The memory device according to claim 3, wherein the plurality of second portions of the dielectric structure are devoid of the liner layer.

5. The memory device according to claim 2, wherein a thickness of the first dielectric layer in the first portion of the dielectric structure is greater than a thickness of the first dielectric layer in the second portion of the dielectric structure.

6. The memory device according to claim 2, wherein a thickness of the second dielectric layer in the second portion of the dielectric structure is greater than a thickness of the second dielectric layer in the first portion of the dielectric structure.

7. The memory device according to claim 2, wherein the first segment of the liner layer comprises a main portion and a protruding portion, the protruding portion being located at an end of the main portion.

8. The memory device according to claim 7, further comprising a stop layer, located on the dielectric structure.

9. The memory device according to claim 8, wherein a top end of the second segment is in contact with the stop layer.

10. The memory device according to claim 9, wherein the top end of the second segment is higher than a top surface of the main portion of the first segment.

11. The memory device according to claim 9, wherein the protruding portion of the first segment of the liner layer is in contact with the stop layer.

12. The memory device according to claim 11, wherein the protruding portion separates the second dielectric layer in the first portion of the dielectric structure from the second dielectric layer in the second portion.

13. The memory device according to claim 12, wherein the second dielectric layer in the plurality of second portions of the dielectric structure is in contact with the stop layer, the second dielectric layer further being in contact with the protruding portion of the first segment of the liner layer and a side wall of the second segment of the liner layer.

14. The memory device according to claim 8, further comprising:
a plurality of third stacked structures, located on the substrate in the peripheral area, wherein the dielectric structure is further located in a third opening between the plurality of third stacked structures, and the liner layer comprises a third segment and a fourth segment, the third segment covering the plurality of third stacked structures, and the fourth segment being embedded in the dielectric structure in the third opening.

15. The memory device according to claim 14, wherein the third segment is connected to the fourth segment.

16. The memory device according to claim 15, wherein the second dielectric layer in the memory array area and the third segment of the liner layer in the peripheral area are coplanar.

17. The memory device according to claim 15, wherein the stop layer further extends into the peripheral area, and the third segment is in contact with the stop layer.

18. A method of fabricating a semiconductor device, comprising:
forming a first stacked structure and a second stacked structure on a substrate;
forming a first dielectric layer and a liner layer on the first stacked structure and the second stacked structure, wherein a step height is formed in the dielectric layer and the liner layer on the second stacked structure;
removing at least a portion of the step height to form a groove;
forming a dielectric material on the liner layer and in the groove;
performing a planarization process on the dielectric material to form a second dielectric layer; and
forming a stop layer on the second dielectric layer.

19. The method of fabricating the semiconductor device according to claim 18, wherein the groove divides the liner layer into a first segment and a second segment, wherein the first segment covers the first stacked structure, and the second segment is around a side wall of the second stacked structure.

20. The method of fabricating the semiconductor device according to claim 19, wherein the first segment comprises a main portion and a protruding portion at an end of the main portion, and performing the planarization process on the dielectric material comprises using the protruding portion of the first segment and the second segment as a polishing stop layer.
